(19) United States
(12) Patent Application Publication
(10) Pub. No.: US 2013/0146844 A1
(43) Pub. Date: Jun. 13, 2013

(54) LIGHT DETECTOR AND METHOD FOR PRODUCING LIGHT DETECTOR

(71) Applicants: Technical Research & Development Institute Minis, Tokyo (JP); Fujitsu Limited, Kawasaki-shi (JP)

(72) Inventors: Goro SUGIZAKI, Shinjuku-ku (JP); Michiya KIBE, Shinjuku-ku (JP); Masatoshi KOYAMA, Shinjuku-ku (JP); Yasuhito UCHIYAMA, Isehara (JP); Yusuke MATSUKURA, Isehara (JP); Ryo SUZUKI, Fujisawa (JP); Tetsuo SAITO, Atsugi (JP); Hironori NISHINO, Isehara (JP)

(73) Assignees: Fujitsu Limited, Kawasaki-shi (JP); Technical Research & Development Institute Ministry of Defense, Japan, Tokyo (JP)

(21) Appl. No.: 13/693,358

(22) Filed: Dec. 4, 2012

(30) Foreign Application Priority Data
Dec. 8, 2011 (JP) 2011-268791

(51) Int. Cl. H01L 31/0352; H01L 31/18

(52) U.S. Cl. CPC H01L 31/035218; H01L 31/18
USPC 257/21; 438/57

(57) ABSTRACT

A first electrode layer is disposed on a substrate and a first active layer is disposed thereon. The first active layer includes a first barrier layer and a plurality of first quantum dots that are distributed in the first barrier layer and have a band gap narrower than that of the first barrier layer. A second electrode layer is disposed on the first active layer. On the second active layer, a second active layer is disposed. The second active layer includes a second barrier layer and a plurality of second quantum dots that are distributed in the second barrier layer and have a band gap narrower than that of the second barrier layer. A third electrode layer is disposed on the second active layer. The first quantum dots are larger than the second quantum dots.

### CROSS-REFERENCE TO RELATED APPLICATION

This application is based upon and claims the benefit of priority of the prior Japanese Patent Application No. 2011-268791, filed on Dec. 8, 2011, the entire contents of which are incorporated herein by reference.

### FIELD

The embodiments discussed herein are related to a light detector having a quantum dot structure and a method for producing the light detector.

### BACKGROUND

Because electromagnetic waves emitted from an object at around room temperature has a high intensity in an infrared wavelength region, an object can be captured by detecting an infrared ray emitted from the object. In addition, because the intensity of an infrared ray emitted from an object is dependent on the temperature of the object, detection of an infrared ray can also be used to estimate the temperature of the object. An infrared detector using, for example, a quantum dot structure is proposed (Japanese Laid-open Patent Publication No. 2007-184512).

### SUMMARY

According to one aspect of the present invention, there is provided a light detector comprising:
a first electrode layer disposed on a substrate;
a first active layer that is disposed on the first electrode layer, and that includes a first barrier layer and a plurality of first quantum dots that are distributed in the first barrier layer and have a band gap narrower than that of the first barrier layer;
a second electrode layer disposed on the first active layer;
a second active layer that is disposed on the second electrode layer, and that includes a second barrier layer and a plurality of second quantum dots that are distributed in the second barrier layer and have a band gap narrower than that of the second barrier layer; and
a third electrode layer disposed on the second active layer,
wherein the first quantum dots are larger than the second quantum dots.

According to another aspect of the present invention, there is provided a method for producing a light detector comprising:
forming a first electrode layer on a substrate;
forming on the first electrode layer, a first active layer including a first barrier layer and a plurality of first quantum dots distributed therein;
forming a second electrode layer on the first active layer;
forming on the second electrode layer, a second active layer including a second barrier layer and a plurality of second quantum dots distributed therein; and
forming a third electrode layer on the second active layer,
wherein:
in the forming of the first active layer, forming of a first repeating unit layer to serve as a part of the first barrier layer and forming of the first quantum dots on the first repeating unit layer are repeated;
in the forming of the second active layer, forming of a second repeating unit layer to serve as a part of the second barrier layer and forming of the second quantum dots on the second repeating unit layer are repeated; and
the substrate temperature during the forming of the second quantum dots is lower than the substrate temperature during the forming of the first quantum dots.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 illustrates a cross section view of a light detector according to an embodiment 1.

FIGS. 2A and 2B are cross section views of a light detector according to the embodiment 1 in intermediate steps of a production process, while FIG. 2C is a plane view schematically illustrating an image wherein first quantum dots and second quantum dots are vertically projected on a virtual plane parallel to the substrate surface.

FIG. 3 is a graph indicting changes in the substrate temperature over time in the film formation process of a light detector according to the embodiment 1.

FIGS. 4A and 4B are graphs indicating the light absorption spectra of a first and second active layers.

FIG. 5A is a cross section view of dimensional changes of quantum dots of a light detector according to the embodiment 1, while FIG. 5B is a cross section view illustrating dimensional changes of quantum dots of a light detector according to a comparative example.

FIG. 6 illustrates a cross section view of a light detector according to an embodiment 2.

FIG. 7 is a cross section view of an imager according to an embodiment 3.

### DESCRIPTION OF THE PREFERRED EMBODIMENTS

The intensity of an electromagnetic wave emitted from an object decreases as the distance from the object increases. More specifically, the intensity of a wavelength component of an electromagnetic wave emitted from an object is dependent on both the temperature of the object and the distance from the object. Therefore, if the distance from an object is uncertain, it is difficult to accurately estimate the temperature of the object based only on the intensity of the electromagnetic wave.

An embodiment of the present application is given below to describe a light detector that can estimate the temperature of an object by detecting an electromagnetic wave emitted from the object and also describe a production process thereof.

### Embodiment 1

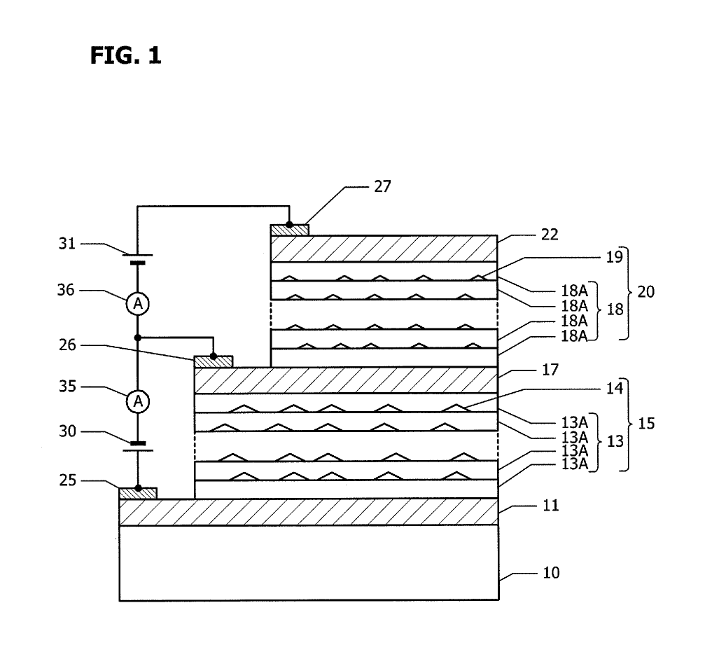

FIG. 1 illustrates a cross section view of a light detector according to the embodiment 1. On a semiconductor substrate 10, a first electrode layer 11 is formed. The semiconductor substrate 10 is formed with, for instance, semi-insulating GaAs. The first electrode layer 11 is formed with, for instance, n-type GaAs and its thickness is 1000 nm. Si is used as n-type impurities and the concentration of the n-type impurities in the first electrode 11 is, for instance, 1×10¹⁸ cm⁻³.

On a part of the first electrode layer 11, a first active layer 15 is disposed. The first active layer 15 includes a first barrier layer 13 and a plurality of quantum dots 14 that are distributed in the first barrier layer 13. The band gap of the first quantum dot 14 is narrower than that of the first barrier layer 13. The first barrier layer 13 has a structure wherein a plurality of first repeating unit layers 13A are stacked. The first quantum dots 14 are distributed on the interface of the first repeating unit layers 13A that are adjacent to each other in the stacking direction.

The first repeating unit layers 13A are formed with, for instance, non-doped AlGaAs with an Al composition ratio of 0.2. The thickness of each first repeating unit layer 13A is, for instance, 50 nm. The first quantum dots 14 are formed with, for instance, InAs. The first barrier layer 13 includes, for instance, 11 first repeating unit layers 13A.

On a first active layer 15, a second electrode layer 17 is formed. The material, impurity concentration, and thickness of the second electrode layer 17 are the same as the material, impurity concentration, and thickness of the first electrode layer 11.

On a part of the second electrode layer 17, a second active layer 20 is disposed. The second active layer 20 includes a second barrier layer 18 and a plurality of second quantum dots 19 that are distributed over the second barrier layer 18. The band gap of the second quantum dots 19 is narrower than that of the second barrier layer 18. The second barrier layer 18 has a structure wherein a plurality of second repeating unit layers 18A are stacked. The second quantum dots 19 are distributed on the interface of the second repeating unit layers 18A that are adjacent to each other in the stacking direction. The volume of a second quantum dot 19 is smaller than that of a first quantum dot 14.

The material and thickness of each second repeating unit layer 18A are the same as the material and thickness of each first repeating unit layer 13A. The material of the second quantum dots 19 is the same as the material of the first quantum dots 14. The number of the stacked second repeating unit layers 18A is the same as the number of the stacked first repeating unit layers 13A.

On the second active layer 20, a third electrode layer 22 is formed. The material, impurity concentration, and thickness of the third electrode 22 are the same as the material, impurity concentration, and thickness of the first electrode 11.

The first electrode layer 11, the second electrode layer 17, and the third electrode layer 22 make ohmic contact with a first electrode 25, a second electrode 26, and a third electrode 27, respectively. The first to third electrodes 25 to 27 have a two-layer structure in which, for instance, AuGe and Au layers are stacked.

A first direct current power supply 30 applies a positive voltage to the first electrode 25 with respect to the second electrode 26. As a result, a current flows through the first active layer 15 in its thickness direction. A second direct current power supply 31 applies a positive voltage to the third electrode 27 with respect to the second electrode 26. As a result, a current flows through the second active layer 20 in its thickness direction. The current flowing through the first active layer 15 is measured with a first ammeter 35, while the current flowing through the second active layer 20 is measured with a second ammeter 36.

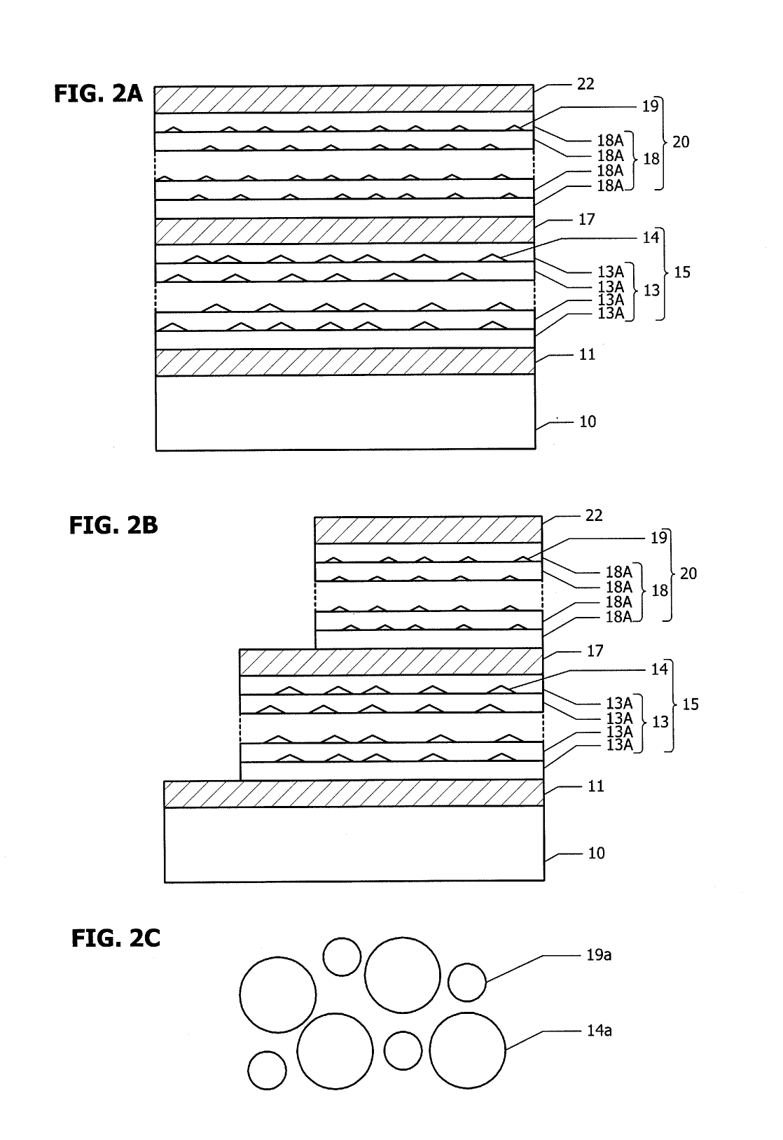

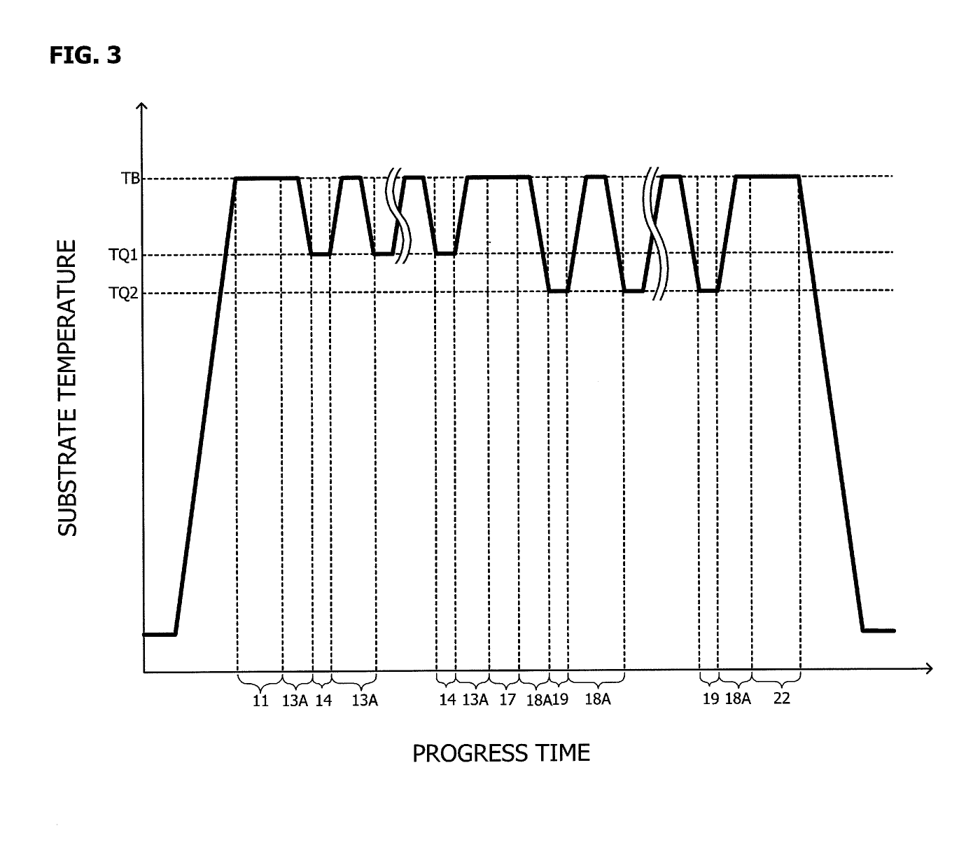

Next, the light detector production process according to the embodiment 1 is explained with reference to FIGS. 2A to 2C and FIG. 3.

FIG. 2A illustrates a cross section view after the formation of semiconductor layers, while FIG. 3 indicates changes in the substrate temperature over time during the formation of semiconductor layers. The horizontal axis in FIG. 3 indicates the progress time, while the reference symbols attached to the horizontal axis correspond to the semiconductor layers (FIG. 2A) formed during the time period. The vertical axis in FIG. 3 indicates the substrate temperature. To form each semiconductor layer, molecular beam epitaxy (MBE) method, for instance, is applied.

The substrate temperature is raised from room temperature to a temperature TB. The temperature TB is, for instance, 600 degrees C. With the substrate temperature maintained at 600 degrees C., a first electrode 11 including n-type GaAs is formed on a semiconductor substrate 10. In addition, repeating unit layers 13A including non-doped AlGaAs are formed thereon. During the formation of the repeating unit layers 13A, the substrate temperature is lowered from TB to TQ1. The substrate temperature TQ1 is, for instance, 500 degrees C.

On conditions that the growth rate is 0.1 mono-layers/s with the substrate temperature maintained at TQ1, InAs material for 2.5 mono-layers is supplied on the substrate. In the process of supplying InAs material, the growth mode transits from two-dimensional growth to three-dimensional growth and first quantum dots 14 are formed in a self-organizing manner.

By supplying AlGaAs material after the first quantum dots 14 are formed, first repeating unit layers 13A are formed. During the formation of the first repeating unit layers 13A, the substrate temperature is raised from TQ1 to TB, and then the substrate temperature is lowered to TQ1 again. After that, formation of first quantum dots 14 and formation of a first repeating unit layer 13A are repeated nine times.

In the formation process of a first repeating unit layer 13A to be disposed at the top, the substrate temperature is raised from TQ1 to TB, and then a second electrode layer 17 is formed with the substrate temperature maintained at TB.

After the second electrode layer 17 is formed, second repeating unit layers 18A are formed. During the formation of the second repeating unit layers, the substrate temperature is lowered from TB to TQ2. The substrate temperature TQ2, which is lower than the substrate temperature TQ1 used during the formation of the first quantum dot 14, is, for instance, 460 degrees C.

On condition that the growth rate is 0.2 mono-layer/s with the substrate temperature maintained at TQ2, InAs material for 2.0 mono-layers are supplied on the substrate. In the process of supplying InAs material, the growth rate transits from two-dimensional growth to three-dimensional growth and second quantum dots 19 are formed in a self-organizing manner. During the formation of second quantum dots 19, the substrate temperature is lower than the temperature during the formation of the first quantum dots 14. Therefore, the aggregation of In atoms and As atoms are suppressed. The fact that InAs material supplying rate (film formation rate) is fast also suppresses the aggregation of In atoms and As atoms. In addition, the material supply for forming second quantum dots 19 is smaller than the material supply for forming first quantum dots 14. Because of these factors, each of the second quantum dots 19 is smaller than each of the first quantum dots 14. Here, the term “small” means that the volume is small and that the area is small in the image that is vertically projected to a virtual plane parallel to the substrate surface.

FIG. 2C illustrates schematic images of first quantum dots and second quantum dots that are vertically projected to a virtual plane parallel to the substrate surface. In the above conditions, 14a and 19a, which are images of a first quantum dot 14 and a second quantum dot and 19, respectively, vertically projected to a virtual plane parallel to the substrate surface, have shapes that are approximated to circles with diameters of 30 nm and 15 nm, respectively. Strictly, a vertically projected image is a polygon because crystal planes with a Miller index of a relatively slow growth rate forms the slopes of a quantum dot, but the polygon can be approximated to be a circle.

By supplying AlGaAs material after the second quantum dots 19 are formed, second repeating unit layers 18A are formed. During the formation of the second repeating unit layers 18A, the substrate temperature is raised from TQ2 to TB, and then the substrate temperature is lowered to the temperature TQ2 again. Then, formation of second quantum dots 19 and formation of a second repeating unit layer 18A are repeated nine times.

In the film formation process of the second repeating unit layer 18A to be disposed at the top, the substrate temperature is raised from TQ2 to TB, and then a third electrode layer 22 is formed with the substrate temperature maintained at TB. Here, the film formation process for semiconductor layers is complete.

As illustrated in FIG. 2B, a part of the first electrode layer 11 is exposed by etching down to the upper surface of the first electrode layer 11 by using general photolithography and dry etching procedures. In addition, a part of the second electrode layer 17 is exposed by etching another region down to the upper surface of the second electrode layer 17.

As illustrated in FIG. 1, a first electrode 25, a second electrode 26, and a third electrode 27 are formed on the exposed upper surface of the first electrode layer 11, the exposed upper surface of the second electrode layer 17, and the exposed upper surface of the third electrode layer 22, respectively, by metal deposition method and the lift-off process.

Next, the behavior of a light detector according to the embodiment 1 is explained. The difference in energy between the base quantum level of the conduction band of the first quantum dot 14 and the lower end of the conduction band of the first barrier layer 13 corresponds to a wavelength in the infrared region. Similarly, the difference in energy between the base quantum level of the conduction band of the second quantum dot 19 and the lower end of the conduction band of the second barrier layer 18 also corresponds to a wavelength in the infrared region.

If an infrared ray with a wavelength corresponding to the difference in energy between the base quantum level of a quantum dot and the lower end of the conduction band of the barrier layer is applied to the active layer including quantum dots, the infrared ray is absorbed and electrons captured at the base quantum level of the quantum dot are excited to the conduction band of the barrier layer. The electrons excited to the conduction band are transported to the positive electrode layer by the electric field applied to the active layer.

As the electrons captured by quantum dots are transported to the electrode layer, the negative space charge density on the active layer decreases. As a result, the potential relative to electrons at the lower end of the conductive band is lowered. The potential at the lower end of the conduction band of the active layer serves as a potential barrier for electrons that are transported through the active layer in the thickness direction. As the potential barrier decreases, the current flowing through the active layer increases. This increase in current is referred to as photoelectric current.

The base quantum level of the relatively larger first quantum dots 14 is deeper than the base quantum level of the relatively smaller second quantum dots 19. As a result, the difference in energy between the base quantum level of the quantum dots in the first active layer 15 and the lower end of the conduction band of the barrier layer is larger than that in the second active layer 20. Therefore, the peak of the infrared absorption spectrum of the first active layer 15 appears on the shorter wavelength side of the peak of the infrared absorption spectrum of the second active layer 20.

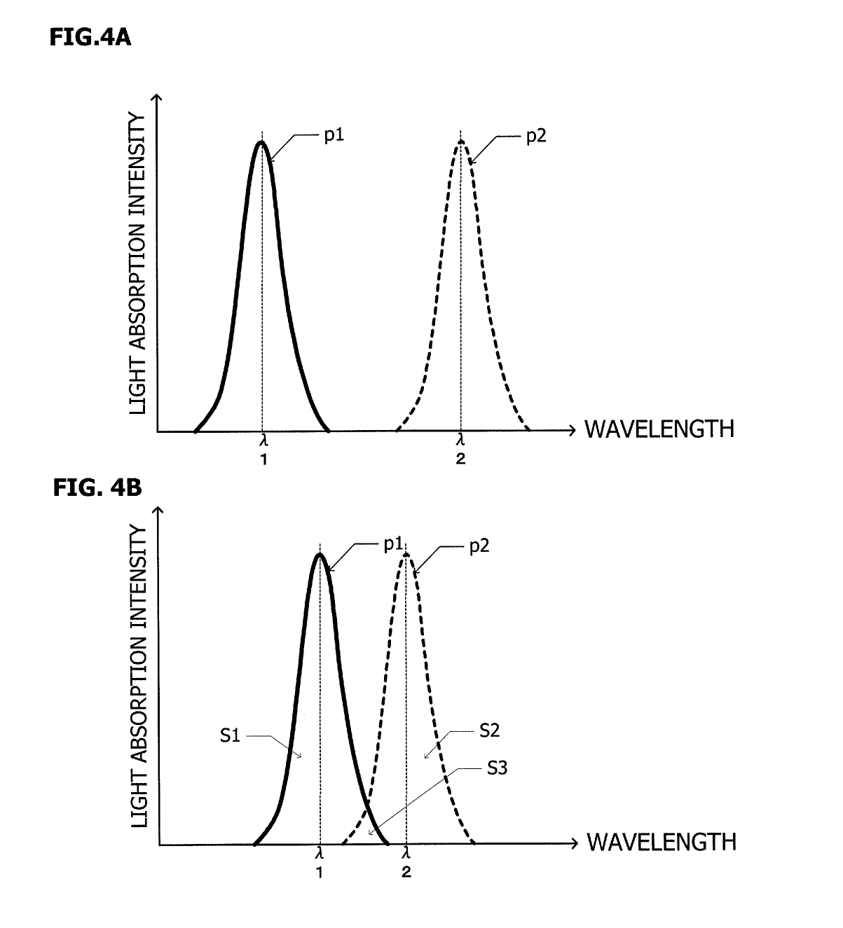

FIG. 4A illustrates an example of the infrared absorption spectra of the first and second active layers 15 and 20. The peak wavelength of the absorption peak p1 for the first active layer 14 is λ1, while the peak wavelength of the absorption peak p2 for the second active layer 20 is λ2, where λ1<λ2.

Separately measuring the photoelectric currents of the first active layer 15 and the second active layer 20 serves to detect the intensities of the components with wavelengths λ1 and λ2 of an infrared ray applied to a light detector.

The intensity ratio between two components with different wavelengths of an infrared ray emitted from an object changes depending on the temperature of the object. By measuring the intensities of the two components with different wavelengths, the temperature of the object can be estimated with little influence of the distance from the object, that is, the attenuation of the infrared ray.

To detect separately the intensities of two components with different wavelengths of an infrared ray, it is preferable that the absorption peak p1 for the first active layer 15 and the absorption peak p2 for the second active layer 20 are clearly separated, as indicated in FIG. 4A.

Even if the absorption peaks p1 and p2 overlap each other at their feet as illustrated in FIG. 4B, the intensities of the two components with different wavelengths can be measured separately as long as the overlap is small. Preferably, the first active layer 15 and the second active layer 20 are designed in such a manner that S3≦0.1×S1 and 3≦0.1×S2, where S1 and S2 are the areas of absorption peaks p1 and p2, respectively, and S3 is the overlap area.

If the average of the areas of the images made by projecting the first quantum dots 14 vertically to a virtual plane parallel to the substrate plane is twice or more of that of the second quantum dots 19, the two absorption peaks p1 and p2 are clearly separated. Note that if the average of the areas of the images made by projecting the first quantum dots 14 vertically to a virtual plane parallel to the substrate plane is at least 1.5 times that of the second quantum dots 19, it will be possible to separate the peaks clearly.

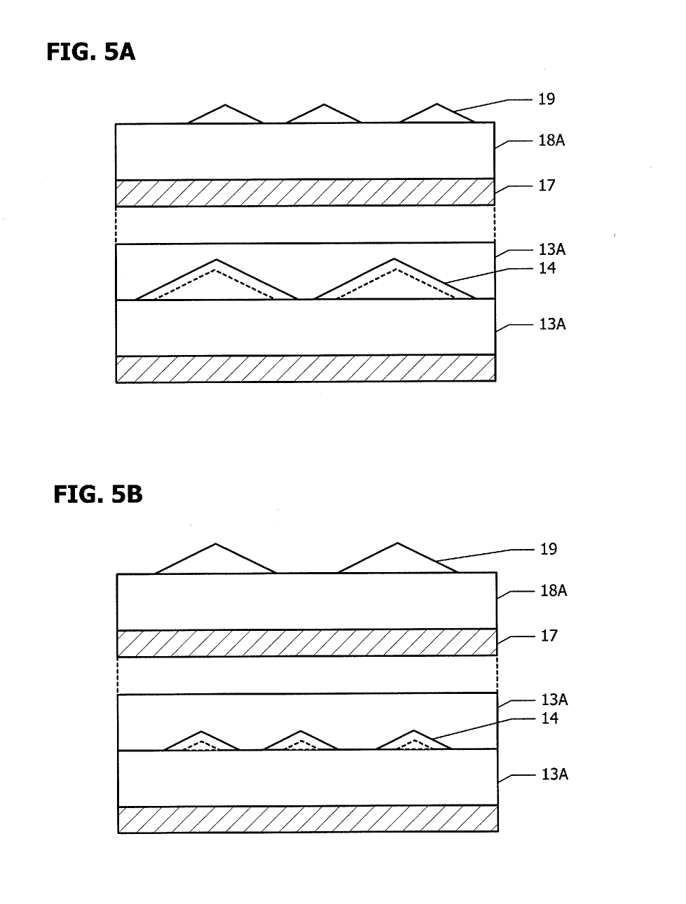

Next, the effect of making the first quantum dots 14 larger than the second quantum dots 19 are explained with reference to FIGS. 5A and 5B.

As illustrated in FIG. 5A, a second electrode 17, second repeating unit layers 18A, and second quantum dots 19 are formed after first quantum dots 14 and first repeating unit layers 13A are formed. As indicated in FIG. 3, after the first quantum dots 14 are formed, the first quantum dots 14 are influenced by the heat history during the formation of semiconductor layers on them. Because of this heat history, In (indium) atoms in the first quantum dots 14 diffuse into the repeating unit layers 13A. As a result, the size of the first quantum dots 14 is reduced as indicated with broken lines. The heat history undergone by the second quantum dots 19 are smaller than the heat history undergone by the first quantum dots 14. Here, the term “heat history” refers to the cumulative value of the products of temperature and time.

FIG. 5B illustrates a fragmentary cross section of a light detector for a comparative example where the first quantum dots 14 are smaller than the second quantum dots 19. Also in this comparative example, the first quantum dots 14 will become smaller due to the subsequent heat history.

In the examples illustrated in FIGS. 5A and 5B, the diffusion distance of In atoms is considered to be almost the same. This means that the volume reduction rate of each first quantum dot 14 according to the embodiment 1 illustrated in FIG. 5A is smaller than the volume reduction rate of each first quantum dot 14 in the comparative example illustrated in FIG. 5B. The volume reduction rate is represented as (V0−V1)/V0, where V0 is the volume of a first quantum dot 14 immediately after formation and V1 is the volume of the first quantum dot 14 after volume reduction.

The depth of the base quantum level changes due to a reduction in the quantum dot volume, the collapse of the potential shape at the lower end of the conduction band caused by the diffusion of In atoms, and the like. In the embodiment 1, variations in the depth of the base quantum level can be suppressed by reducing the volume reduction rate of each first quantum dot 14, resulting in the suppression of variations in the wavelength where the light absorption peak appears. This makes it possible to provide a light detector having desired detection characteristics.

As explained above, the light intensities of two components with different wavelengths can be detected based on a dimensional difference made between the first quantum dots included in the first active layer and the second quantum dots included in the second active layer. This eliminates the influence of the distance from an object, making it possible to estimate the temperature of an object. In addition, a decrease the relative size of the quantum dots disposed on the substrate side serves to reduce the influence of the heat history undergone by quantum dots.

### Embodiment 2

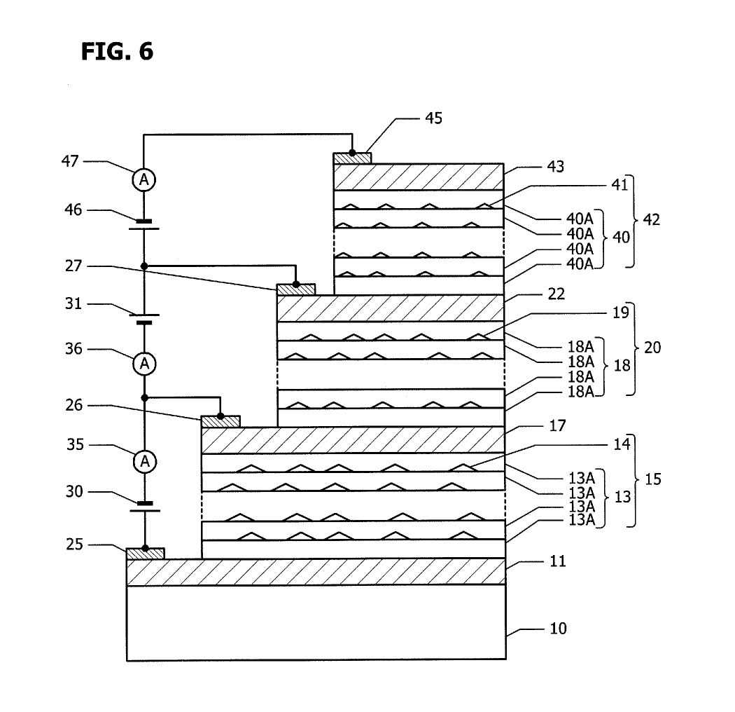

FIG. 6 illustrates a cross section view of a light detector according to the embodiment 2. Differences from the light detector according to the embodiment 1 illustrated in FIG. 1 are explained in the following. Note that explanation for common constitutional features is omitted.

In the embodiment 2, a third active layer 42 and a fourth electrode layer 43 are further formed on the third electrode layer 22. The third active layer 42 includes a third barrier layer 40 and third quantum dots 41 as in the first active layer 15 and the second active layer 20. The third barrier layer 40 contains a plurality of third repeating unit layers 40A. The third quantum dots 41 are smaller than the second quantum dots 19.

A fourth electrode 45 makes ohmic contact with the upper surface of the fourth electrode 43. A third direct current power supply 46 applies a direct current voltage between the third electrode 27 and the fourth electrode 45. This voltage allows a current to flow through the third active layer 42 in the thickness direction. A third ammeter measures currents flowing through the third active layer 42.

The peak wavelength in the light absorption spectrum of the third active layer 42 is longer than that of the second active layer 20. The light detector according to the embodiment 2 can detect the intensities of three components with different wavelengths in the infrared range, making it possible to enhance the estimation accuracy of the temperature of an object. In this case, it is preferable that the area of the image made by vertically projecting each second quantum dot 19 on a virtual plane parallel to the substrate plane be 1.5 times or more of the area of the image made by vertically projecting each third quantum dot 41 on a virtual plane parallel to the substrate plane.

### Embodiment 3

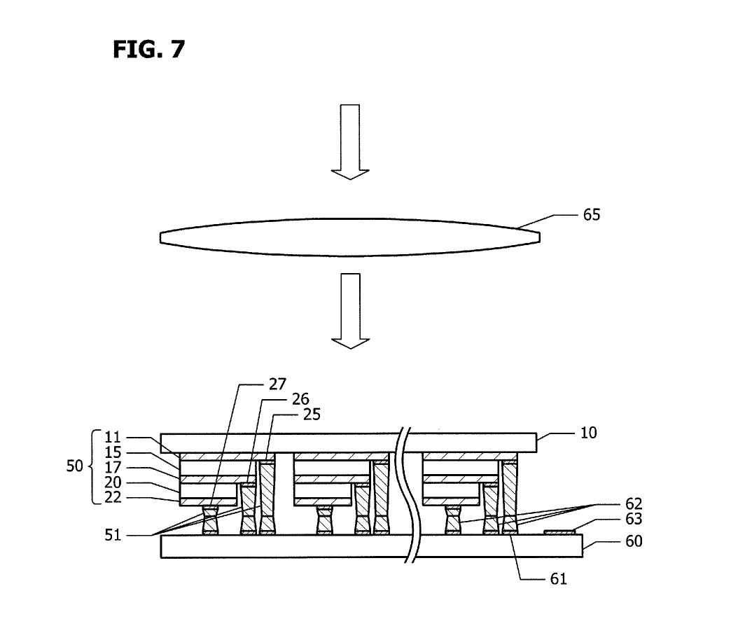

FIG. 7 illustrates a schematic cross section view of an imager according to the embodiment 3. On the surface of a semiconductor substrate 10, a plurality of light detectors 50 are disposed. Each of the light detectors 50 has the same configuration as the light detector according to the embodiment 1. The reference symbol for each component in FIG. 7 corresponds to that for the component of the light detector 50 according to the embodiment 1 illustrated in FIG. 1. The light detectors 50 are distributed in one- or two-dimensional manner.

A bump 51 is formed on each of a first electrode 25, a second electrode 26, and a third electrode 27.

An integrated circuit substrate 60 is disposed so as to face that surface of the substrate 10 on which the light detectors 50 are formed. On the semiconductor substrate 60, CMOS circuits are formed to replace the first and second direct current voltage sources 30 and 31 and the first and second ammeters 35 and 36 illustrated in FIG. 1. On a position corresponding to each of the first to third electrodes 25 to 27 on the surface of the integrated circuit substrate 60, an electrode pad 61 is formed and a bump 62 is formed thereon. The bumps 51 and 62 are formed with, for instance, indium (In). Each bump 51 connected to a light detector 50 and each bump 62 formed on the integrated circuit substrate 60 are fixed to each other.

On the surface of the integrate circuit substrate 60, a plurality of electrode terminals 63 are further formed. Through each electrode terminal 63, control signals are entered to the CMOS circuits formed on the integrated circuit substrate 60. Image signals detected with the light detectors 50 are output externally through the electrode terminals 63.

A lens 65 is placed in front of the semiconductor substrate 10 (in the space opposite to that where the integrated circuit substrate 60 is disposed). An infrared ray emitted from a point of an object and condensed by the lens 65 forms an infrared ray image on a line or plane on which light detectors 50 are arranged.

Because each of the light detectors 50 has the same structure as the light detector according to the embodiment 1, the light detectors 50 can detect the intensities of two components with different wavelengths in the infrared wavelength region.

Though light detectors for infrared rays are described in the embodiments 1 to 3 in the above, the configurations according to the embodiments 1 to 3 can also be applied to light detectors for rays with wavelengths outside the infrared region. In addition, though non-doped semiconductor materials are used for the first active layer 15, the second active layer 20, and the third active layer 42 in the embodiments 1 to 3, they may have n-type conductivity. This may reduce the element resistance.

The first electrode layer 11, the second electrode layer 17, the third electrode layer 22, and the fourth electrode layer 43 may have p-type conductivity. When infrared rays are absorbed in this case, the holes captured at the base quantum level on the valence electron band side of a quantum dot are excited to the valence electron band on the barrier layer. When a p-type electrode layer is used, AuZn is used as an ohmic electrode.

In the above embodiments 1 to 3, AlGaAs is used for a barrier layer and InAs is used for quantum dots, but other compound semiconductors may be used on condition that the band gap of the quantum dots is narrower than the band gap of the barrier layer. For example, InAs, GaAs, AlAs, or mixed crystals of these compound semiconductors may be used for the quantum dots and the barrier layer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What are claimed are:

1. A light detector comprising:
a first electrode layer disposed on a substrate;
a first active layer that is disposed on the first electrode layer, and that includes a first barrier layer and a plurality of first quantum dots that are distributed in the first barrier layer and have a band gap narrower than that of the first barrier layer;
a second electrode layer disposed on the first active layer;
a second active layer that is disposed on the second electrode layer, and that includes a second barrier layer and a plurality of second quantum dots that are distributed in the second barrier layer and have a band gap narrower than that of the second barrier layer; and
a third electrode layer disposed on the second active layer,
wherein the first quantum dots are larger than the second quantum dots.

2. The light detector according to claim 1, wherein the average of the areas of images made by vertically projecting the first quantum dots to a virtual plane parallel to the substrate surface is twice or more of the average of the areas of images made by vertically projecting the second quantum dots.

3. The light detector according to claim 1, wherein the relations S3≦0.1×S1 and S3≦0.1×S2 hold, where S1 is the area of the peak in the light absorption spectrum of the first active layer corresponding to the difference in energy between the base quantum level of the first quantum dots and the lower end of the conduction band of the first barrier layer, S2 is the area of the peak in the light absorption spectrum of the second active layer corresponding to the difference in energy between the base quantum level of the second quantum dots and the lower end of the conduction band of the second barrier layer, and S3 is the overlap area between the peak in the light absorption spectrum of the first active layer and the peak in the light absorption spectrum of the second active layer.

4. The light detector according to claim 1, further comprising:
a third active layer that is disposed on the third electrode layer, and that includes a third barrier layer and a plurality of third quantum dots that are distributed in the third electrode layer and have a band gap narrower than that of the third barrier layer; and
a fourth electrode layer disposed on the third active layer,
wherein the second quantum dots are larger than the third quantum dots.

5. A method for producing a light detector comprising:
forming a first electrode layer on a substrate;
forming on the first electrode layer, a first active layer including a first barrier layer and a plurality of first quantum dots distributed therein;
forming a second electrode layer on the first active layer;
forming on the second electrode layer, a second active layer including a second barrier layer and a plurality of second quantum dots distributed therein; and
forming a third electrode layer on the second active layer,
wherein:
in the forming of the first active layer, forming of a first repeating unit layer to serve as a part of the first barrier layer and forming of the first quantum dots on the first repeating unit layer are repeated;
in the forming of the second active layer, forming of a second repeating unit layer to serve as a part of the second barrier layer and forming of the second quantum dots on the second repeating unit layer are repeated; and
the substrate temperature during the forming of the second quantum dots is lower than the substrate temperature during the forming of the first quantum dots.

6. The method according to claim 5, wherein the materials are supplied in such a manner that the growth rate for the forming of the second quantum dots is higher than the growth rate for the forming of the first quantum dots.

7. The method according to claim 5, wherein:
in the forming of the first repeating unit layers, the substrate temperature during the growing of the first repeating unit layers is raised from the substrate temperature at the time of forming the first quantum dots, and then lowered to the same substrate temperature as that at the time of forming the first quantum dots; and
in the forming of the second repeating unit layers, the substrate temperature during the growing of the second repeating unit layers is raised from the substrate temperature at the time of forming the second quantum dots, and then lowered to the same substrate temperature as that at the time of forming the second quantum dots.
